(19) United States
(12) Patent Application Publication
(10) Pub. No.: US 2024/0247673 A1
(43) Pub. Date: Jul. 25, 2024

(54) FASTENING DEVICE

(71) Applicants: Innolux Corporation, Miaoli County (TW); CARUX TECHNOLOGY PTE. LTD., SINGAPORE (SG)

(72) Inventors: I-Jan Wang, Miaoli County (TW); Ching-I Lo, Tainan (TW)

(73) Assignees: Innolux Corporation, Miaoli County (TW); CARUX TECHNOLOGY PTE. LTD., SINGAPORE (SG)

(21) Appl. No.: 18/402,624

(22) Filed: Jan. 2, 2024

(30) Foreign Application Priority Data
Jan. 19, 2023 (CN) 202310059806.7

(51) Int. Cl. F16B 21/12; F16B 2/14; F16B 45/04; F16B 5/00

(52) U.S. Cl. CPC F16B 21/125; F16B 2/14; F16B 45/059; F16B 5/0096; F16B 2200/10; F16B 2200/403; F16B 2200/67

(57) ABSTRACT

A fastening device including a back plate, a rear cover and an elastic piece is provided. The rear cover is arranged on the back plate and has a protruding portion. The elastic piece is arranged between the back plate and the rear cover. The elastic piece has a first opening, and the protruding portion passes through the first opening, and the first opening is a tooth-shaped structure.

### CROSS-REFERENCE TO RELATED APPLICATION

This application claims the priority benefit of China application serial no. 202310059806.7, filed on Jan. 19, 2023. The entirety of the above-mentioned patent application is hereby incorporated by reference herein and made a part of this specification.

### BACKGROUND

### Technical Field

The disclosure relates to a connecting device, and particularly relates to a fastening device.

### Description of Related Art

For current products such as in-vehicle screens, TVs, or desktop screens, etc., joining of a rear cover and a back plate is limited by appearance requirements, i.e., screw holes are not allowed to be seen directly, so that nameplates and decorative strips are added to a surface of the screw holes to modify the appearance. However, the above-mentioned method will not only increase material cost, but also increase production cost duo to that the added nameplates or decorative strips cannot be reworked.

### SUMMARY

The disclosure is directed to a fastening device, which reduces the use of assembly parts (such as screws).

An embodiment of the disclosure provides a fastening device including a back plate, a rear cover and an elastic piece. The rear cover is arranged on the back plate and has a protruding portion. The elastic piece is arranged between the back plate and the rear cover. The elastic piece has a first opening, and the protruding portion passes through the first opening, and the first opening is a tooth-shaped structure.

Based on the above description, in the embodiment of the disclosure, the elastic piece is arranged between the back plate and the rear cover, and the protruding portion of the rear cover may pass through the first opening with the tooth-shaped structure of the elastic piece, so that the rear cover and the back plate may have a clamping and fixing effect through interference assembly. Therefore, by using the fastening device of the disclosure, when the rear cover of the appearance part is assembled, it is unnecessary to use additional assembly parts (such as screws).

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic three-dimensional cross-sectional view of a fastening device according to an embodiment of the disclosure.

FIG. 2 is a schematic top view of an elastic piece of the fastening device in FIG. 1.

FIG. 3 is a schematic diagram of the elastic piece and a protruding portion of a rear cover of the fastening device in FIG. 1.

FIG. 4 is a schematic three-dimensional view of a fastening device according to another embodiment of the disclosure.

FIG. 5 is a schematic three-dimensional view of a fastening device according to another embodiment of the disclosure.

### DESCRIPTION OF THE EMBODIMENTS

The disclosure may be understood by referring to the following detailed description in conjunction with the accompanying drawings. It should be noted that, in order to facilitate readers' understanding and keep the drawings concise, several drawings in the disclosure only depict a part of the electronic device. Also, certain components in the drawings are not drawn to actual scales. In addition, the number and size of each component in the figure are only for illustration, and are not intended to limit the scope of the disclosure.

Certain terms will be used throughout the specification and appended claims of the disclosure to refer to particular components. Those skilled in the art should understand that electronic device manufacturers may refer to the same component by different names. This document does not intend to distinguish between those components that have the same function but have different names.

In the following description and claims, terms such as “containing” and “comprising” are open-ended words, so that they should be interpreted as meaning “including but not limited to . . . ”

Moreover, relative terms such as “below” or “bottom” and “above” or “top” may be used in the embodiments to describe a relative relationship of one component to another component in the drawings. It may be understood that if the device in the drawing is turned over so that it is upside down, the component described as being on the “lower” side would then be oriented on the “upper” side.

In some embodiments of the disclosure, terms related to bonding and connecting mentioned in the specification, such as “connected”, “interconnected”, etc., unless specifically defined, may mean that two structures are in direct contact with each other, or that two structures are not in direct contact with each other, but there are other structures located between the above two structures. The terms of bonding and connecting may also include a situation that both structures are movable or both structures are fixed. In addition, the term “couple” includes transfer of energy between two structures by means of direct or indirect electrical connection, or transfer of energy between two separate structures by means of mutual induction.

It should be understood that when a component or film layer is referred to as being “on” or “connected to” another component or film layer, it may be directly on or directly connected to the another component or film layer, or there are intervening components or film layers there between (indirect connection). In contrast, when a component is referred to as being “directly on” or “directly connected to” another component or film layer, there are no intervening components or film layers there between.

In the disclosure, a measurement method of a length, width, thickness, height or area, or a distance or spacing between components may be implemented by using an optical microscope (OM), a scanning electron microscope (SEM), a film thickness profilometer (α-step), an ellipsometer, or other suitable means. In detail, according to some embodiments, the SEM may be used to obtain cross-sectional structure images including the components to be measured, and measure the length, width, thickness, height or area of each component, or the distance or spacing between components, but the disclosure is not limited thereto.

In addition, the terms “a given range is from a first numerical value to a second numerical value” and “a given range falls within a range from the first numerical value to the second numerical value” mean that the given range includes the first numerical value, the second numerical value and their other values there between. If a first direction is perpendicular to a second direction, an angle between the first direction and the second direction may be between 80 degrees and 100 degrees; if the first direction is parallel to the second direction, the angle between the first direction and the second direction may be between 0 degrees and 10 degrees. The terms “about”, “equal”, “equivalent” or “identical”, “substantially” or “approximately” are generally interpreted as being within 20% of a given value or range, or as being within 10%, 5%, 3%, 2%, 1%, or 0.5% of the given value or range.

Although the terms first, second, third . . . may be used to describe various constituent components, the constituent components are not limited to these terms. These terms are only used to distinguish a single constituent component from other constituent components in the specification. The same terms may not be used in the claims, but may be replaced by first, second, third . . . in an order in which components are declared in the claims. Therefore, in the following description, a first constituent component may be a second constituent component in the claims.

Unless otherwise defined, all terms (including technical and scientific terms) used herein have the same meaning as commonly understood by those with ordinary skills in the art to which this disclosure belongs. It is understood that these terms, such as those defined in commonly used dictionaries, should be interpreted as having a meaning consistent with the background or context of the related art and the disclosure, and not interpreted in an idealized or overly formal manner, unless specifically defined herein.

It should be noted that in the following embodiments, technical features in several different embodiments may be replaced, reorganized, and mixed to complete other embodiments without departing from the spirit of the disclosure.

Reference will now be made in detail to the exemplary embodiments of the disclosure, examples of which are illustrated in the accompanying drawings. Wherever possible, the same reference numbers will be used in the drawings and description to refer to the same or like parts.

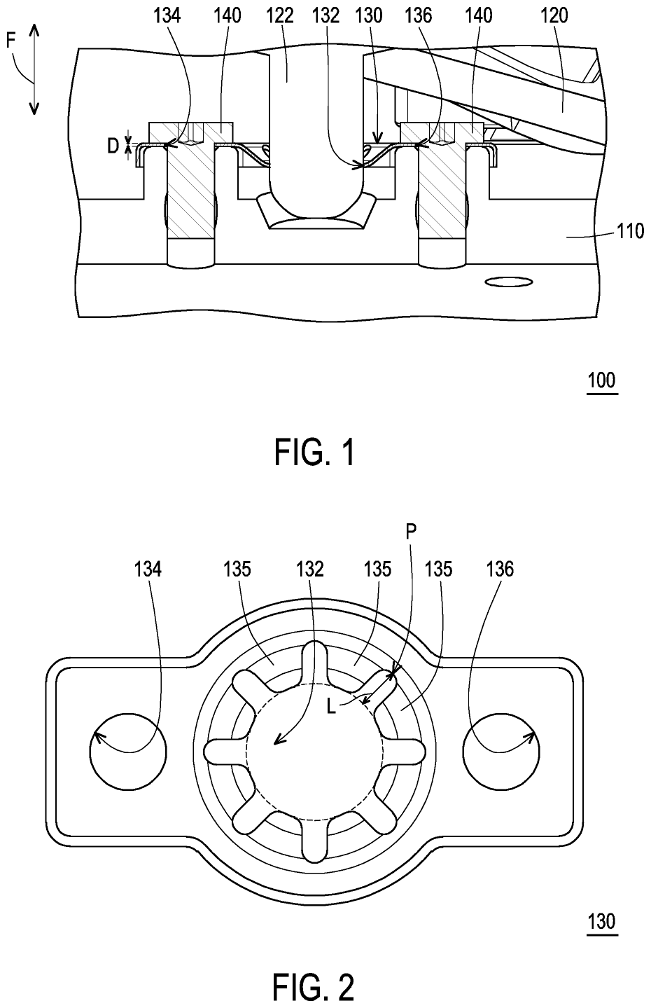

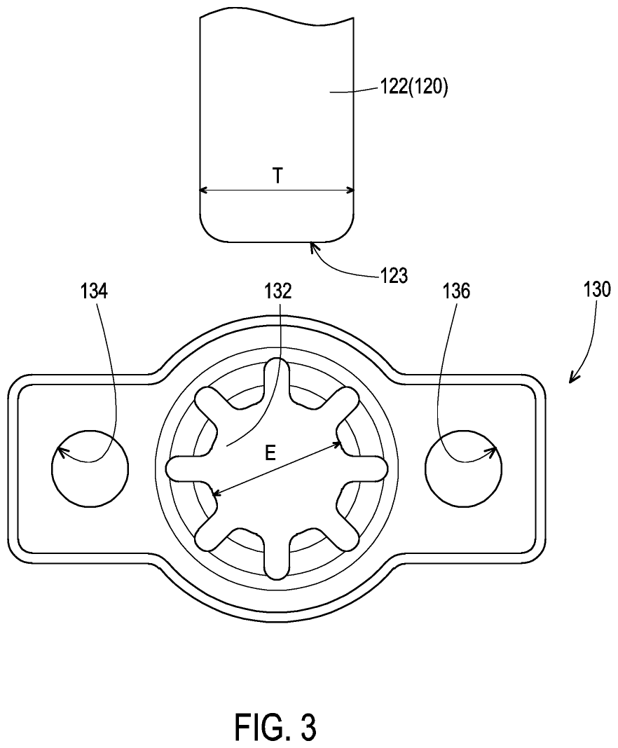

FIG. 1 is a schematic three-dimensional cross-sectional view of a fastening device according to an embodiment of the disclosure. FIG. 2 is a schematic top view of an elastic piece of the fastening device in FIG. 1. FIG. 3 is a schematic diagram of the elastic piece and a protruding portion of a rear cover of the fastening device in FIG. 1.

Referring to FIG. 1 and FIG. 2 at the same time, in the embodiment, a fastening device 100 includes a back plate 110, a rear cover 120 and an elastic piece 130. The rear cover 120 is disposed on the back plate 110 and has a protruding portion 122. The elastic piece 130 is disposed between the back plate 110 and the rear cover 120. The elastic piece 130 has a first opening 132, the protruding portion 122 passes through the first opening 132, and the first opening 132 is a tooth-shaped structure.

In detail, in the embodiment, the protruding portion 122 may be screwed or integrally formed on the rear cover 120, which is not limited here. The elastic piece 130 in the embodiment further has a second opening 134 and a third opening 136, where the second opening 134 and the third opening 136 are respectively located on two sides of the first opening 132. Top view shapes of the second opening 134 and the third opening 136 are, for example, circular, but the disclosure is not limited thereto. In addition, the fastening device 100 of the embodiment may further include a plurality of fixing members 140, which are disposed on the elastic piece 130 and pass through the second opening 134 and the third opening 136 for fixing the elastic piece 130 to the back plate 110. Here, the fixing members 140 may be, for example, screws or a bolts, but the disclosure is not limited thereto. Namely, the elastic piece 130 of the embodiment may be fixed on the back plate 110 by means of screw locking, but the disclosure is not limited thereto.

As shown in FIG. 1, the elastic piece 130 of the embodiment has a thickness D, where the thickness D is, for example, between 0.2 mm and 0.4 mm (0.2 mm≤thickness D≤0.4 mm). The thickness D mentioned here is a thickness of an original plate of the elastic piece 130, and the opening and the tooth-shaped structure may be formed by, for example, punching the original plate. If the thickness D of the elastic piece 130 is less than 0.2 mm, the elastic piece 130 has no clamping effect. If the thickness D of the elastic piece 130 is greater than 0.4 mm, the elastic piece 130 is too rigid and is not easy to be assembled.

Referring to FIG. 2 again, the tooth-shaped structure (i.e., the first opening 132) of the embodiment includes a plurality of protrusions 135, where a number of the protrusions 135 is between 5 and 10, for example. If the number of the protrusions 135 is less than 5, the protrusions 135 have a too large size and are not easy to be engaged. If the number of the protrusions 135 is greater than 10, the protrusions 135 have a too small size and are easy to be damaged. In addition, each protrusion 135 of the tooth-shaped structure has a length L, each tooth top surface of the tooth-shaped structure is connected to form a virtual inner circle, and each tooth groove of the tooth-shaped structure has an end point P, a minimum distance between the virtual inner circle and the end point P is defined as the length L, and the length L is, for example, between 1.5 mm and 2.0 mm (1.5 mm≤length L≤2.0 mm), which may avoid an insufficient cantilever distance of the protrusion 135 to cause uneasy deformation and engaging.

Referring to FIG. 2 and FIG. 3 at the same time, the protruding portion 122 of the rear cover 120 has a thickness T, and the first opening 132 of the elastic piece 130 has a minimum width E, where the thickness T is greater than the minimum width E. Preferably, the thickness T and the minimum width E have a difference range of 0.1 mm to 0.3 mm, which is an interference amount between the protrusion 135 and the protruding portion 122. If the interference amount between the protrusion 135 and the protruding portion 122 is too small, there will be no clamping effect. If the interference amount between the protrusion 135 and the protruding portion 122 is too much, it is not conducive to assembly and rework. In addition, the protruding portion 122 in the embodiment has a top surface 123, and the top surface 123 may be a beveled or rounded structure, which may be used as a correction structure for misalignment during assembly.

Referring to FIG. 1 again, when the rear cover 120 and the back plate 110 are assembled, the protruding portion 122 of the rear cover 120 may be aligned with the first opening 132 of the elastic piece 130, and along a force applying direction F, the protruding portion 122 is interfered with the first opening 132 in a manner of direct forward pressing to achieve an engaging effect. When the rear cover 120 and the back plate 110 are disassembled, the protruding portion 122 of the rear cover 120 may be detached in a direction reverse to the force applying direction F, so that the rear cover 120 is separated from the back plate 110.

It should be noted that although the protruding portion 122 here is embodied in a cylindrical shape, the disclosure is not limited thereto. Since the embodiment achieves the engaging effect through the interference assembling of the protruding portion 122 of the rear cover 120 and the first opening 132 of the elastic piece 130, the above effect may be achieved as long as the shape of the protruding portion 122 of the rear cover 120 and the shape of the first opening 132 of the elastic piece 130 may have an interference effect. Therefore, the protruding portion 122 of the rear cover 120 may also be in a suitable shape such as a square column, a triangular column, an elliptical column, etc., all of which belong to a protection scope of the disclosure.

In brief, in the embodiment of the disclosure, the elastic piece 130 is disposed between the back plate 110 and the rear cover 120, and the protruding portion 122 of the rear cover 120 may pass through the first opening 132 of the elastic sheet 130 in the tooth-shaped structure, such that the rear cover 120 and the back plate 110 may achieve a clamping and fixing effect by interference assembly. Therefore, the fastening device 100 of the disclosure makes it unnecessary to use additional assembly parts (such as screws) when assembling the rear cover 120 of the appearance part.

It should be noted that the following embodiments use the component referential numbers and partial content of the previous embodiment, where the same referential numbers are used to denote the same or similar components, and descriptions of the same technical content are omitted. For the description of omitted parts, reference may be made to the foregoing embodiments, and will not be repeated in the following embodiments.

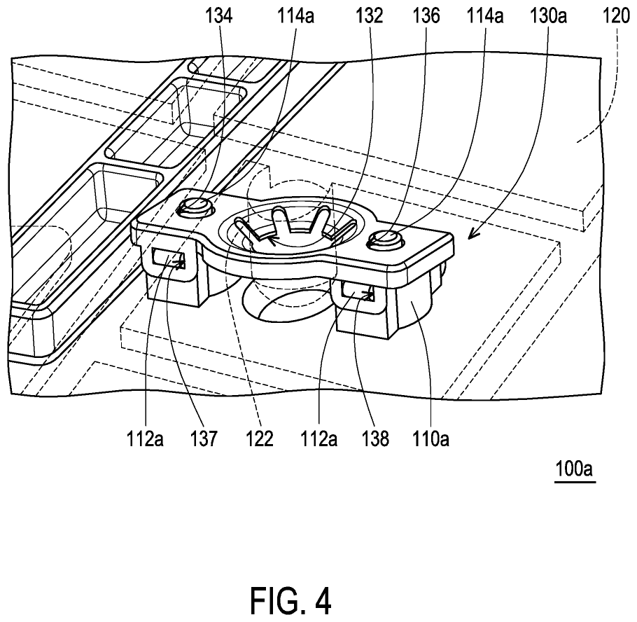

FIG. 4 is a schematic three-dimensional view of a fastening device according to another embodiment of the disclosure. Referring to FIG. 1 and FIG. 4 at the same time, a fastening device 100a of the embodiment is similar to the fastening device 100 of FIG. 1, and the same parts are not repeated here. A difference between FIG. 1 and FIG. 4 is that in this embodiment, an elastic piece 130a is fixed on a back plate 110a by means of engaging and fixing.

In detail, the back plate 110a has a plurality of hooks 112a and a plurality of positioning posts 114a, and the elastic piece 130a further has a plurality of fourth openings 137 and a plurality of fifth openings 138. The second opening 134 and the third opening 136 of the elastic piece 130a are engaged and fixed with the positioning posts 114a of the back plate 110a, and the fourth opening 137 and the fifth opening 138 of the elastic piece 130a are engaged fixed with the hooks 112a of the back plate 110a, so as to engage and fix the elastic piece 130a on the back plate 110a. The hooks 112a and the positioning posts 114a are respectively disposed on different surfaces of the back plate 110a, where the hooks 112a and the positioning posts 114a are, for example, arranged by perpendicular to each other.

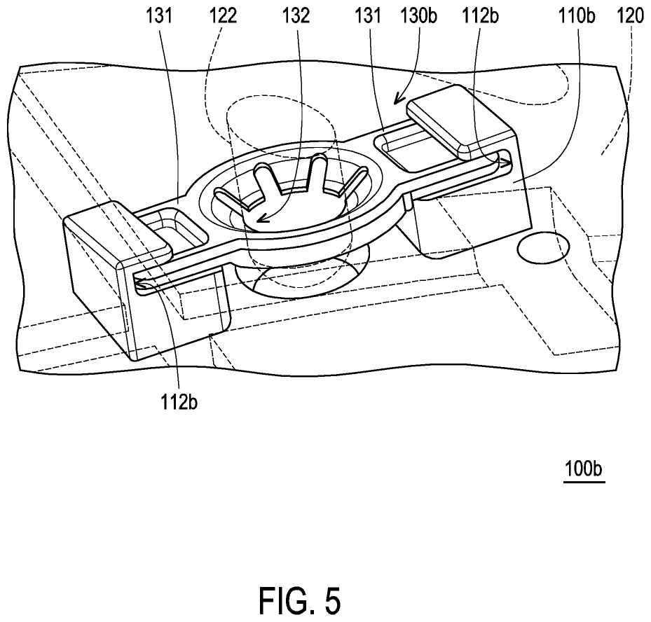

FIG. 5 is a schematic three-dimensional view of a fastening device according to another embodiment of the disclosure. Referring to FIG. 1 and FIG. 5 at the same time, a fastening device 100b of the embodiment is similar to the fastening device 100 in FIG. 1, and the same parts are not repeated here. A difference between FIG. 1 and FIG. 5 is that in the embodiment, an elastic piece 130b is fixed on a back plate 110b by fitting and fixing.

In detail, the back plate 110b has two fitting grooves 112b, and the elastic piece 130b further has two fitting portions 131. The two fitting portions 131 of the elastic piece 130b are respectively fitted and fixed with the two fitting grooves 112b of the back plate 110b, so that the elastic piece 130b is fitted and fixed on the back plate 110b.

In brief, the elastic piece 130 of the disclosure may be, for example, fixed on the back plate 110 by screw locking; or, the elastic piece 130a may be fixed on the back plate 110a by, for example, structural engagement; or, the elastic piece 130b may be fixed on the back plate 110b by, for example, fitting; or, the elastic piece may be fixed on the back plate by, for example, thermal melting, which all belong to the protection scope of the disclosure.

In addition, although the protruding portion 122 is configured on the rear cover 120 in the disclosure, in another embodiment that is not illustrated, the protruding portion may also be configured on the back plate, and the elastic piece is configured between the back plate and the rear cover, and the protruding portion of the back plate may pass through the first opening of the tooth-shaped structure of the elastic piece, so that the back cover and the back plate may achieve the clamping and fixing effect by interference assembly, which still belongs to the protection scope of the disclosure.

In summary, in the embodiments of the disclosure, the elastic piece is arranged between the back plate and the rear cover, and the protruding portion of the rear cover may pass through the first opening with the tooth-shaped structure of the elastic piece, so that the rear cover and the back plate may have a clamping and fixing effect through interference assembly. Therefore, the fastening device of the disclosure may reduce the use of assembly parts (such as screws).

It will be apparent to those skilled in the art that various modifications and variations can be made to the disclosed embodiments without departing from the scope or spirit of the disclosure. In view of the foregoing, it is intended that the disclosure covers modifications and variations provided they fall within the scope of the following claims and their equivalents.

What is claimed is:

1. A fastening device, comprising:
a back plate;
a rear cover, arranged on the back plate and having a protruding portion; and
an elastic piece, arranged between the back plate and the rear cover, wherein the elastic piece has a first opening, and the protruding portion passes through the first opening, and the first opening is a tooth-shaped structure.

2. The fastening device as claimed in claim 1, wherein the elastic piece further has a second opening and a third opening, and the second opening and the third opening are respectively located on two sides of the first opening.

3. The fastening device as claimed in claim 2, further comprising:
a plurality of fixing members, arranged on the elastic piece, and passing through the second opening and the third opening to fix the elastic piece on the back plate.

4. The fastening device as claimed in claim 3, wherein the plurality of fixing members comprise a plurality of screws or a plurality of bolts.

5. The fastening device as claimed in claim 2, wherein the elastic piece has a thickness ranging from 0.2 mm to 0.4 mm.

6. The fastening device as claimed in claim 2, wherein top view shapes of the second opening and the third opening are both circular.

7. The fastening device as claimed in claim 2, wherein the back plate has a plurality of hooks and a plurality of positioning posts, and the elastic piece further has a plurality of fourth openings and a plurality of fifth openings, the second opening and the third opening of the elastic piece are engaged and fixed with the plurality of positioning posts of the back plate, and the fourth openings and the fifth openings of the elastic piece are engaged and fixed with the plurality of hooks of the back plate.

8. The fastening device as claimed in claim 7, wherein the elastic piece is fixed on the backboard through structural engagement.

9. The fastening device as claimed in claim 7, wherein the plurality of hooks and the plurality of positioning posts are respectively arranged on different surfaces of the back plate.

10. The fastening device as claimed in claim 9, wherein the plurality of hooks and the plurality of positioning posts are arranged by perpendicular to each other.

11. The fastening device as claimed in claim 1, wherein the tooth-shaped structure comprises a plurality of protrusions, and a number of the plurality of protrusions is between 5 and 10.

12. The fastening device as claimed in claim 11, wherein each of the protrusions of the tooth-shaped structure has a length, and the length is between 1.5 mm and 2.0 mm.

13. The fastening device as claimed in claim 1, wherein he protruding portion has a thickness, and the first opening has a minimum width, and the thickness is greater than the minimum width.

14. The fastening device as claimed in claim 13, wherein the thickness and the minimum width have a difference range of 0.1 mm to 0.3 mm.

15. The fastening device as claimed in claim 1, wherein the protruding portion has a top surface, and the top surface is a beveled or rounded structure.

16. The fastening device as claimed in claim 1, wherein the protruding portion is screwed or integrally formed on the rear cover.

17. The fastening device as claimed in claim 1, wherein a shape of the protruding portion comprises a cylinder, a square column, a triangular column or an elliptical column.

18. The fastening device as claimed in claim 1, wherein the back plate has two fitting grooves, and the elastic piece further has two fitting portions, and the two fitting portions of the elastic piece are respectively fitted and fixed with the two fitting grooves of the back plate.

19. The fastening device as claimed in claim 18, wherein the elastic piece is fixed on the back plate through structural fitting.

20. The fastening device as claimed in claim 1, wherein the elastic piece is fixed on the back plate by thermal melting.
